(19) United States
(12) Patent Application Publication
(10) Pub. No.: US 2026/0231498 A1
(43) Pub. Date: Aug. 6, 2026

(54) METHODS FOR CONTROLLING PASSIVATING CONTACT THICKNESS IN BACKSIDE CONTACT SOLAR CELLS

(71) Applicant: Maxeon Solar Pte. Ltd., Singapore (SG)

(72) Inventors: Gerly Reich, San Jose, CA (US); David D. Smith, Campbell, CA (US)

(73) Assignee: Maxeon Solar Pte. Ltd., Singapore (SG)

(21) Appl. No.: 19/042,012

(22) Filed: Jan. 31, 2025

(51) Int. Cl. H10D 64/01; H10F 19/80; H10F 77/70

(52) U.S. Cl. CPC H10D 64/021; H10F 19/807; H10F 77/703

(57) ABSTRACT

A method of forming a solar cell is disclosed. The method includes forming a multilayered stack of materials wherein a first amorphous silicon layer is the top layer of the multilayered stack of materials and is formed above an oxide layer that is formed above a second amorphous silicon layer. In addition, the method includes forming a plurality of openings in the first amorphous silicon layer, forming a plurality of non-contiguous mask regions in the second amorphous silicon layer, and forming a plurality of trenches around each non-contiguous mask region of the plurality of non-contiguous mask regions to form a plurality of non-contiguous first silicon regions and to form one or more second silicon regions, wherein the plurality of non-contiguous first silicon regions include parts of a first portion of the second amorphous silicon layer on their top surfaces, wherein the parts of the first portion of the second amorphous silicon layer includes the plurality of non-contiguous mask regions, and wherein the one or more second silicon regions include parts of a second portion of the second amorphous silicon layer on the top surface of the one or more second silicon regions. The method further includes removing the plurality of non-contiguous mask regions to expose the top surfaces of the plurality of non-contiguous first silicon regions.

### TECHNICAL FIELD

Embodiments of the disclosure pertain to passivating contact thickness and, in particular, to passivating contact thickness in backside contact solar cells.

### BACKGROUND

Solar cells are devices for converting solar radiation to electrical energy. They may be fabricated on a semiconductor wafer using semiconductor processing technology. A solar cell includes p-type and n-type doped regions. Solar radiation impinging on the solar cell creates electrons and holes that migrate to the doped regions and create voltage differentials between them that generate electrical current. In a backside contact solar cell, both doped regions and metal contacts are located on the backside of the solar cell. The metal contacts allow external electric circuits to be coupled to and powered by the solar cell. Efficiency is an important characteristic of solar cells that is related to their capacity to generate power. However, there are significant challenges related to the design and fabrication of solar cells with improved efficiency.

### BRIEF DESCRIPTION OF THE DRAWINGS

FIG. 1A illustrates an exemplary operating environment of photovoltaic modules having solar cells whose passivating contacts have thicknesses that has been controlled according to one embodiment.

FIG. 1B shows a cross-section of a portion of a solar cell whose passivating contacts have thicknesses that have been controlled according to one embodiment.

FIG. 1C illustrates the positioning of a plurality of trenches around a plurality of polysilicon structures in the solar cell of FIG. 1B according to one embodiment.

FIG. 1D illustrates the positioning of a trench around a polysilicon structure in the solar cell of FIG. 1B according to one embodiment.

FIGS. 2A-2G are illustrations of cross-sections of a multilayered semiconductor structure during fabrication of a solar cell according to one embodiment.

### DESCRIPTION OF THE EMBODIMENTS

Methods for controlling passivating contact thickness in backside contact solar cells are described. It should be appreciated that although embodiments are described herein with reference to example methods for controlling passivating contact thickness in backside contact solar cells, the disclosure is more generally applicable to methods for controlling passivating contact thickness in backside contact solar cells as well as other type methods for controlling passivating contact thickness in backside contact solar cells. In the following description, numerous specific details are set forth, in order to provide a thorough understanding of embodiments of the present disclosure. It will be apparent to one skilled in the art that embodiments of the present disclosure may be practiced without these specific details. In other instances, well-known features, are not described in detail in order to not unnecessarily obscure embodiments of the present disclosure. Furthermore, it is to be appreciated that the various embodiments shown in the Figures are illustrative representations and are not necessarily drawn to scale.

Certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

As used herein the term “diffusion” is intended to refer to the precisely controlled introduction of dopants into a material, by means of a solid, liquid or gaseous source, to give the material desired properties.

As used herein the term “diffused region” is intended to refer to a region of a volume of material, where dopants have been introduced by diffusion, that has a larger concentration of dopants than does the volume of material in general.

As used herein the term “doped region” is intended to refer to a region of a volume of material, where dopants have been introduced, that has a larger concentration of dopants than does the volume of material in general.

As used herein the term “doping” is intended to refer to the introduction of impurity elements into material to give the material desired properties.

In one embodiment, as used herein “doping” can be performed by methods that can include but are not limited to diffusion and ion implantation.

In one embodiment, as used herein the term “dotted” is intended to refer to a structural organization of polysilicon in a solar cell that is characterized by the presence of an ordered plurality of non-contiguous and electrically separated polysilicon islands that are surrounded by trenches.

In one embodiment, as used herein the term “polysilicon” is intended to refer to polysilicon, or polysilicon that contains impurities that can include but are not limited to oxygen and carbon.

In one embodiment, as used herein the term “backside” is intended to refer to a backside of a solar cell that is opposite to the front side of the solar cell, wherein the front side of the solar cell faces the sun during normal operation. In one embodiment, as used herein the term “backside contact solar cell” is intended to refer to a solar cell where all electrical connections to its collection regions are formed on its backside. In one embodiment, in a backside contact solar cell, both doped regions and interdigitated metal contact fingers coupled to them, are located on the backside of the solar cell. In one embodiment, the contact fingers allow an external electrical circuit to be coupled to and powered by the solar cell.

In one embodiment, the term “non-contiguous” polysilicon is intended to refer to non-continuous and separated portions of polysilicon. In particular, to a plurality of non-continuous and separated (by surrounding trenches) polysilicon islands having a bounded periphery that can include various shapes.

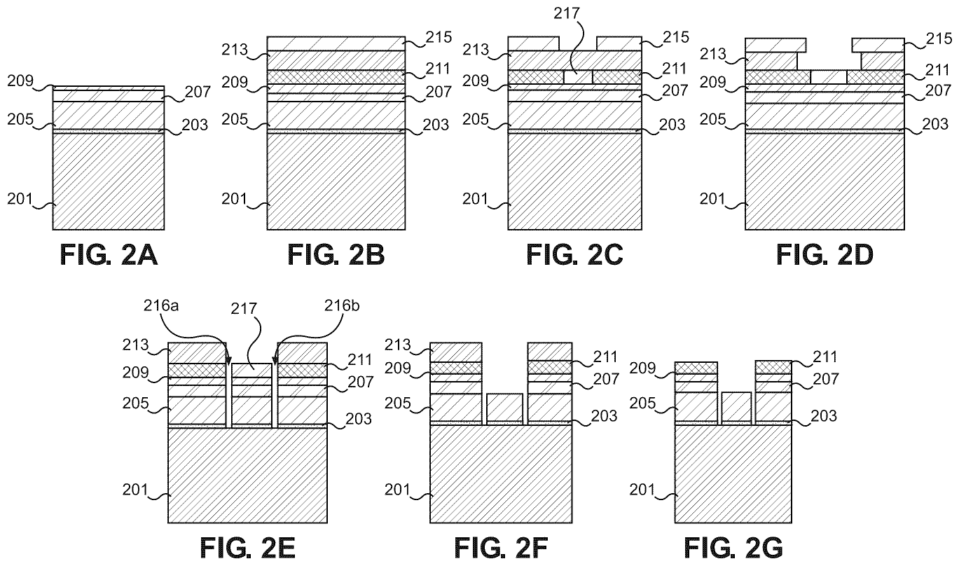

It should be appreciated that in the description of the fabrication processes described with reference to FIGS. 2A-2G, the amorphous silicon layer 211 is referred to as the first amorphous silicon layer as it is the first of two disclosed amorphous silicon layers 211 and 215 that are formed as part of the processes. However, in the claims appended hereto, the same amorphous silicon layer 211 is referred to as the second amorphous silicon layer as between the two claimed amorphous silicon layers 211 and 215 as it is the second amorphous silicon layer to be introduced in the appended claims.

Solar cells convert solar radiation to electrical energy. A solar cell typically includes p-type and n-type doped regions. Solar radiation impinging the surface of the solar cell creates electrons and holes that migrate to the doped regions and cause voltage differentials to develop between the doped regions. In a backside contact solar cell, the doped regions and metal contacts that are coupled to them are located on the backside of the solar cell. The metal contacts allow an external electrical circuit to be coupled to and powered by the solar cell.

Passivating contacts are charge carrier (electrons and holes) selective contacts that are used in silicon based solar cells. Two types of passivating contacts are n and p type contacts that include polycrystalline silicon on a thin dielectric layer such as SiOₓ. n and p type polycrystalline silicon on a thin dielectric layer such as SiOₓ contacts are respectively, electron, and hole, selective, high-efficiency contacts.

Solar cell efficiency is an important operational characteristic of solar cells as solar cell efficiency is directly related to a solar cell's capacity to generate power. The structure of solar cell contacts is an important factor as regards solar cell efficiency. In particular, if the fabrication of solar cell contacts results in excessively etched portions of polysilicon regions of the solar cell, high recombination can occur. High recombination can reduce the efficiency of the solar cell.

Some conventional techniques for masking polysilicon (the polysilicon that is used to form the solar cell contact) during etching operations are not sufficiently robust to provide desired contact thickness. This is because weak masking can result in an etch rate that is excessively rapid and polysilicon that is overly etched. Approaches are needed that provide masking that can adequately protect polysilicon during etching processes.

A method of forming a solar cell is disclosed herein that addresses the aforementioned challenges. In one embodiment, the method includes forming a multilayered stack of materials wherein a first amorphous silicon layer is the top layer of the multilayered stack of materials and is formed above an oxide layer that is formed above a second amorphous silicon layer. In addition, in one embodiment the method includes forming a plurality of openings in the first amorphous silicon layer, forming a plurality of non-contiguous mask regions in the second amorphous silicon layer, and forming a plurality of trenches around each non-contiguous mask region of the plurality of non-contiguous mask regions to form a plurality of non-contiguous first silicon regions and to form one or more second silicon regions, wherein the plurality of non-contiguous first silicon regions include parts of a first portion of the second amorphous silicon layer on their top surfaces, wherein the parts of the first portion of the second amorphous silicon layer includes the plurality of non-contiguous mask regions, and wherein the one or more second silicon regions include parts of a second portion of the second amorphous silicon layer on the top surface of the one or more second silicon regions. In one embodiment, the method further includes removing the plurality of non-contiguous mask regions to expose the top surfaces of the plurality of non-contiguous first polysilicon regions.

In one embodiment, using the processes that are described herein, to establish the thickness of polysilicon passivating contacts, ensures that the polysilicon passivating contacts are effective collectors of charge carriers. In particular, it enables the solar cells to operate in a manner that avoids the substantial loss of generated electricity that can be due to the inability of contacts to effectively collect photogenerated charge carriers. Accordingly, the polysilicon passivating contacts described herein are structured to have a favorable effect on solar cell efficiency.

### Solar Cell

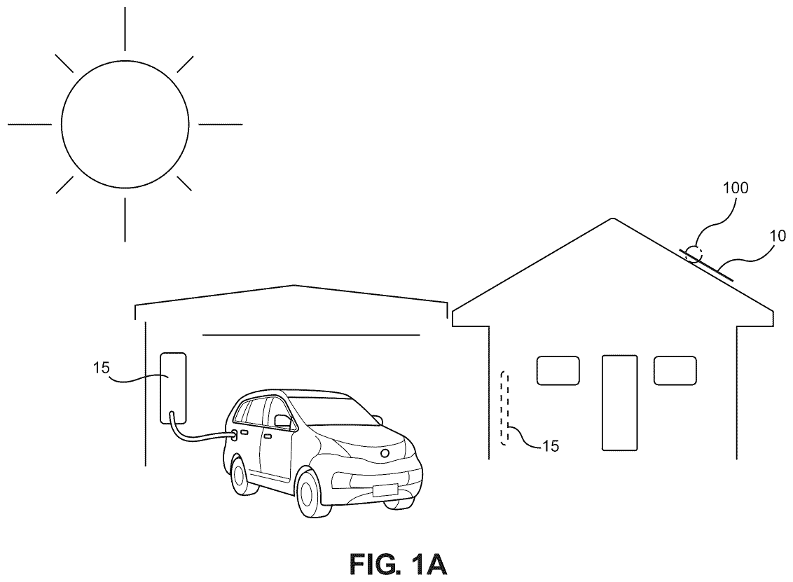

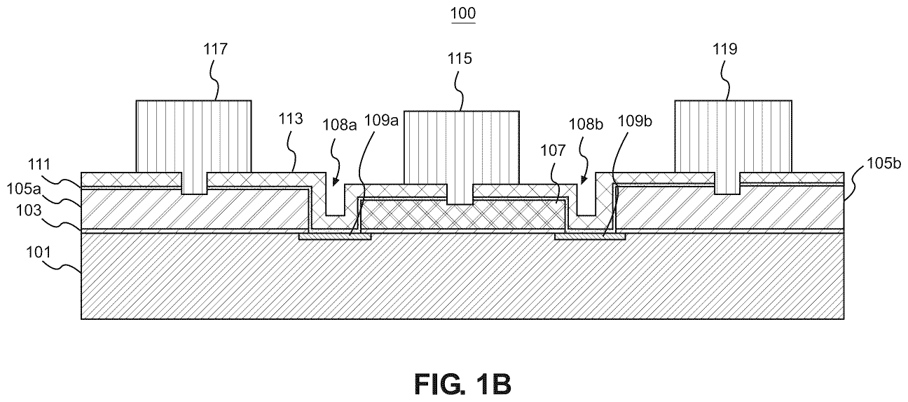

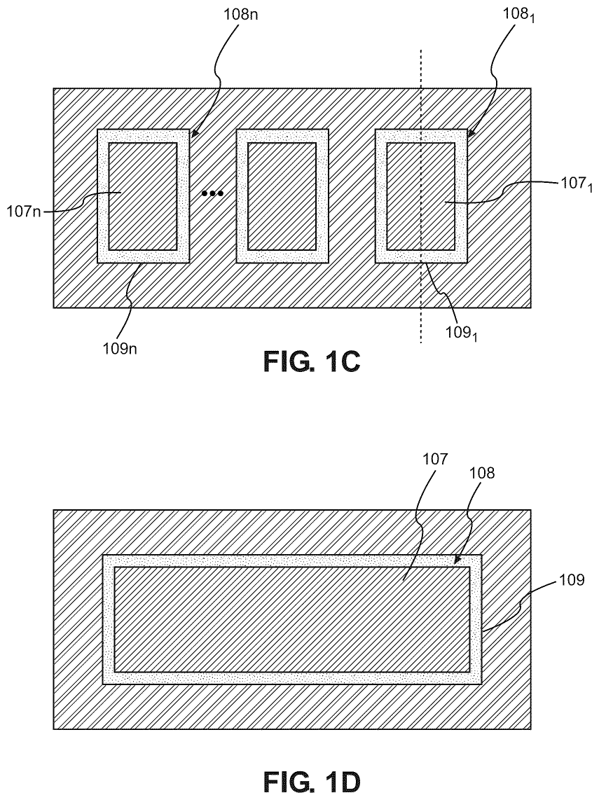

FIG. 1A illustrates an exemplary operating environment of photovoltaic modules having solar cells that are fabricated using methods for controlling blistering in passivating contacts of backside contact solar cells according to one embodiment. FIG. 1A shows a house that has photovoltaic modules 10 that include solar cells 100 (hereinafter “the solar cells” or “a solar cell” or “the solar cell”) that are installed on its roof. In one embodiment, the photovoltaic modules 10 utilize the electrical energy generated by the solar cells to supply the house with electricity (e.g., to power appliances 15). It should be noted that the depicted residential operating environment is only exemplary and that embodiments are equally useful in many other types of operating environments such as commercial environments.

FIG. 1B shows a cross-section of a portion of a solar cell 100 (such as are a part of the photovoltaic modules 10) according to one embodiment. In one embodiment, the solar cell 100 includes wafer 101, tunnel oxide 103, n-doped polysilicon region 105a, n-doped polysilicon region 105b, p-doped polysilicon layer 107₁, trench 108a, trench 108b, doped region 109a, doped region 109b, dielectric layer 111, dielectric layer 113, conductor layer 115, conductor layer 117, conductor layer 119, dielectric layer 121, and dielectric layer 123.

Referring to FIG. 1B, the wafer 101 forms the substrate upon which the semiconductor, dielectric and conductor layers of the solar cell 100 are formed. In one embodiment, the tunnel oxide 103 is formed on the surface of the wafer 101 and includes spaces through which the doped regions 109a and 109b are formed, and in which the dielectric layer 111 is formed. In one embodiment, the p-doped polysilicon layer 107₁ is formed on a portion of the tunnel oxide 103 between laterally situated n-doped polysilicon region 105a and n-doped polysilicon region 105b. In one embodiment, the p-doped polysilicon layer 107₁ includes sides that are covered by the dielectric layer 111 and a top surface that is partially covered by the dielectric layer 111. In addition, in one embodiment, the p-doped polysilicon layer 107₁ is contacted on its top surface through a space in the dielectric layer 111 by conductor layer 115. In one embodiment, the n-doped polysilicon regions 105a and 105b are formed on the surface of the tunnel oxide 103 and are separated from the p-doped polysilicon layer 107₁ by portions of the dielectric layer 111 that extend into the space that surrounds the p-doped polysilicon layer 107₁. In one embodiment, the doped region 109a is formed in the wafer 101 below a portion of the dielectric layer 111 that extends into a first space in the tunnel oxide 103. In addition, in one embodiment, the doped region 109a laterally extends underneath a portion of the tunnel oxide 103 that is formed underneath the p-doped polysilicon layer 107₁ and a portion of the tunnel oxide 103 that is formed underneath the n-doped polysilicon region 105a. In one embodiment, the doped region 109b is formed in the wafer 101 below a portion of the dielectric layer 111 that extends into a second space in the tunnel oxide 103. In addition, in one embodiment, the doped region 109b laterally extends underneath a portion of the tunnel oxide 103 that is formed underneath the p-doped polysilicon layer 107₁ and a portion of the tunnel oxide 103 that is formed underneath the n-doped polysilicon region 105b. In one embodiment, the dielectric layer 111 extends along the top and inner side surface of the n-doped polysilicon region 105a, on the surface of the wafer 101 between the n-doped polysilicon region 105a and the p-doped polysilicon layer 107₁, along the top and side surfaces of the p-doped polysilicon layer 107₁, on the surface of the wafer 101 between the p-doped polysilicon layer 107₁ and the n-doped polysilicon region 105b, and along the top and inner side surface of the n-doped polysilicon region 105b. In one embodiment, the dielectric layer 113 covers and extends along the entire the top surface of the dielectric layer 111. In one embodiment, the dielectric layer 111 and the dielectric layer 113 include an opening above the n-doped polysilicon region 105a that enables the n-doped polysilicon region 105a to be contacted by the conductor layer 117. In one embodiment, the dielectric layer 111 and the dielectric layer 113 include an opening above the p-doped polysilicon layer 107₁ that enables the p-doped polysilicon layer 107₁ to be contacted by the conductor layer 115. In one embodiment, the dielectric layer 111 and the dielectric layer 113 include an opening above the n-doped polysilicon region 105b that enables the n-doped polysilicon region 105b to be contacted by the conductor layer 119.

Referring to FIG. 1C, in one embodiment, the trenches 108a and 108b, shown in FIG. 1B, are opposite side cross-sectional parts of a trench 108₁ that is formed around the p-doped polysilicon layer 107₁ (a cross-sectional representation of a first polysilicon island of a plurality of polysilicon islands). Moreover, in one embodiment, the trench 108₁ is one of a plurality of trenches 108₁-108n formed around the plurality of polysilicon islands 107₁-107n (that constitute non-contiguous or “dotted” passivating contact regions) in solar cell 100 (see FIG. 1C). In one embodiment, the trenches can have shapes that can include but are not limited to circular, rectangular, elongated, elliptical, polygonal and irregular. In one embodiment, the trenches 108₁-108n are formed using a self-aligned process that is described herein with reference to FIGS. 2A-2G. In one embodiment, the polysilicon islands 107₁-107n are a plurality of non-contiguous doped polysilicon regions of p-type conductivity that are formed in lasered regions of the semiconductor structure (see FIGS. 2A-2G).

Referring again to FIG. 1B, in one embodiment, the wafer 101 can be formed from silicon. In other embodiments, the wafer 101 can be formed from other materials. In one embodiment, the tunnel oxide 103 can be formed from silicon oxide. In other embodiments, the tunnel oxide 103 can be formed from other materials. In one embodiment, the n-doped polysilicon regions 105a and 105b can be doped with phosphorous. In other embodiments, the n-doped polysilicon regions 105a and 105b can be doped with other impurities. In one embodiment, the p-doped polysilicon layer 107₁ can be doped with boron. In other embodiments, the p-doped polysilicon layer 107₁ can be doped with other impurities. In one embodiment, the doped regions 109a and 109b can be doped with boron. In other embodiments, the doped regions 109a and 109b can be doped with other materials. In one embodiment, the dielectric layer 111 can include borosilicate glass. In other embodiments, dielectric layer 111 can include other materials. In one embodiment, the dielectric layer 113 can include silicon nitride. In other embodiments, the dielectric layer 113 can include other materials. In one embodiment, the conductor layer 115 can include aluminum, nickel, chromium, gold, germanium, copper, silver, titanium, tungsten, tin, platinum, and tantalum. In other embodiments, the conductor layer 115 can include other materials. In one embodiment, the conductor layer 117 can include aluminum, nickel, chromium, gold, germanium, copper, silver, titanium, tungsten, tin, platinum, and tantalum. In other embodiments, the conductor layer 117 can include other materials. In one embodiment, the conductor layer 119 can include aluminum, nickel, chromium, gold, germanium, copper, silver, titanium, tungsten, tin, platinum, and tantalum. In other embodiments, the conductor layer 119 can include other materials.

### Operation

In operation, upon exposure to light, the solar cells 100 converts light energy into electricity based on the photovoltaic effect. Some carriers reach the p-n junction and contribute to the current produced by the solar cells 100. However, other carriers recombine with no net contribution to the current produced by the solar cells 100. Solar cell efficiency is an important operational characteristic of solar cells as solar cell efficiency is directly related to its capacity to generate power. The solar cells 100 include contacts that are structured to enhance solar cell efficiency. In particular, the solar cells 100 are structured to include contacts that have a level of thickness, that avoids the substantial loss of generated electricity that can be due to the inability of contacts to effectively collect photogenerated charge carriers. The ability of the solar cells 100 to effectively collect charge carriers buttresses the efficiency of the solar cells 100.

### Solar Cell Fabrication Process

FIGS. 2A-2G are illustrations of cross-sections of a multilayer semiconductor structure 200 during fabrication of a solar cell according to one embodiment. Referring to 2A, a cross-section of the multilayer semiconductor structure 200 is shown after initial operations that include depositing a multilayer stack of dielectrics in plasma enhanced chemical vapor deposition (PECVD) or atmospheric pressure chemical vapor deposition (APCVD) onto an intrinsic silicon layer that is formed above a wafer. In one embodiment, the semiconductor structure 200 includes wafer 201, tunnel oxide dielectric 203, intrinsic silicon layer 205, n-type silicon layer 207, and intrinsic silicon layer 209.

Referring to FIG. 2B, after one or more operations resulting in the cross-section shown in FIG. 2A, a first amorphous silicon layer 211, a borosilicate glass (BSG) layer 213, and a second amorphous silicon layer 215 are formed above intrinsic silicon layer 209.

Referring to FIG. 2C, after one or more operations resulting in the cross-section shown in FIG. 2B, a laser patterning process is executed. In particular, in one embodiment, in a first laser pass (of a laser operation), a single laser pulse is used to ablate the second amorphous silicon layer 215. And, in a second laser pass, a laser pulse is used to cause boron to diffuse from the BSG layer 213 into the first amorphous silicon layer 211 to form a-Si mask 217.

Referring to FIG. 2D, after one or more operations that result in the cross-section shown in FIG. 2C, a selective etch (dielectric) is performed. In one embodiment, the selective etch is an oxide etch using hydrofluoric acid. In one embodiment, a highly concentrated hydrofluoric acid solution is used to perform the selective etch. In other embodiments, other substance can be used to perform the oxide etch. In one embodiment, the high hydrofluoric acid concentration is due to the high boron concentration in BSG layer 213. In one embodiment, the oxide etch completely removes the exposed portions of the BSG layer 213.

Referring to FIG. 2E, after one or more operations that result in the cross-section shown in FIG. 2D, a selective etch (semiconductor) is performed. In one embodiment, the selective etch is a silicon etch. In one embodiment, potassium hydroxide (KOH) is used to perform the silicon etch. In one embodiment, as part of the silicon etch, trenches 216a and 216b are formed. It should be appreciated that trenches 216a and 216b are opposite side cross-sectional views of parts of the same trench. In addition, as part of the silicon etch, a plurality of silicon regions or “islands” is formed. In one embodiment, the trench represented by trenches 216a and 216b, is one of a plurality of trenches that circumscribe a plurality silicon islands or “dots” (see FIG. 1C).

In one embodiment, the selective etch (silicon) also removes the second a-Si layer 215. In one embodiment, the selective etch is a low concentration KOH etch. In other embodiments, other substances can be used to perform the selective etch (silicon). In one embodiment, the silicon in the dot area is not etched.

Referring to FIG. 2F, after one or more operations that result in the cross-section shown in FIG. 2E, silicon etch back operations are performed. In one embodiment, as part of the etch back operations, the a-Si mask 217, and, n-type silicon material and intrinsic silicon material, that are protected by the a-Si mask 217, are removed. In one embodiment, the etch back operations are high concentration KOH etches, with low boron selectivity. In other embodiments, other substance can be used to perform the etch back operations.

Referring to FIG. 2G, after one or more operations that result in the cross-section shown in FIG. 2F, an oxide etch is performed. In one embodiment, the oxide etch is a high concentration HF etch. In other embodiments, other substance can be used to perform the high oxide etch. In one embodiment, the oxide etch is performed to remove the remaining portions of the BSG layer 213.

Some conventional processes utilize weak etch masks that are created based on insufficient Boron diffusion. Such processes may not provide p-type polysilicon contacts of sufficient thickness. In one embodiment, the use of amorphous silicon as a layer into which Boron is diffused during laser processes facilitates an incorporation of more boron and provides a better etch mask.

KOH etching of boron doped surfaces has an etch rate that is strongly dependent on the doping level. For example, for very high concentrations of dopants, etch rate goes as the inverse fourth power of concentration. Hence, the use of high levels of boron is very favorable for masking. And, it should be appreciated that, amorphous silicon is better at incorporating those dopants than crystalline or polycrystalline silicon.

In one embodiment, an amorphous silicon layer is deposited on top of an intrinsic polysilicon layer. In one embodiment, this is done to enable a diffusion of boron (using a laser process) into a part of the amorphous silicon layer in order to provide a strong etch mask in order to protect the p-type silicon region. In one embodiment, remnants of the amorphous silicon layer remain on the n-type silicon region providing added thickness to the solar cell.

In one embodiment, in subsequent operations, a high temperature drive operation (high temperature anneal operations) at temperatures above 500 degrees Celsius can be used that crystallizes the silicon layers of the multilayer semiconductor structure 200.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of the present disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of the present application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

The various features of different embodiments may be variously combined with some features included and others excluded to suit a variety of different applications.

What is claimed is:

1. A method of forming a solar cell, comprising:
forming a multilayered stack of materials wherein a first amorphous silicon layer is the top layer of the multilayered stack of materials and is formed above an oxide layer that is formed above a second amorphous silicon layer;
forming a plurality of openings in the first amorphous silicon layer;
forming a plurality of non-contiguous mask regions in the second amorphous silicon layer;
forming a plurality of trenches around each non-contiguous mask region of the plurality of non-contiguous mask regions
to form a plurality of non-contiguous first silicon regions and to form one or more second silicon regions,
wherein the plurality of non-contiguous first silicon regions include parts of a first portion of the second amorphous silicon layer on their top surfaces wherein the parts of the first portion of the second amorphous silicon layer includes the plurality of non-contiguous mask regions, and
wherein the one or more second silicon regions include parts of a second portion of the second amorphous silicon layer on the top surface of the one or more second silicon regions; and
removing the plurality of non-contiguous mask regions to expose the top surfaces of the plurality of non-contiguous first silicon regions.

2. The method of claim 1, wherein the forming a plurality of non-contiguous mask regions in the second amorphous silicon layer includes doping regions of the second amorphous silicon layer through the plurality of openings.

3. The method of claim 1, further comprising, after removing the plurality of non-contiguous mask regions, forming a first doped material on exposed surfaces of remaining portions of the multilayered stack of materials and using the first doped material to cause the plurality of non-contiguous first silicon regions to have a first doping type.

4. The method of claim 1, further comprising after removing the plurality of non-contiguous mask regions, using ion implantation to cause the plurality of non-contiguous first silicon regions to have a first doping type.

5. The method of claim 1, wherein the one or more second silicon regions include doped material formed above the one or more second silicon regions.

6. The method of claim 5, wherein the doped material is used to cause the one or more second silicon regions to have the second doping type.

7. The method of claim 5, further comprising using the doped material to cause the parts of the second portion of the second amorphous silicon layer on the top surface of the one or more second silicon regions to have the second doping type.

8. The method of claim 1, further comprising causing the parts of the second portion of the second amorphous silicon layer on the top surface of the one or more second silicon regions to become polycrystalline.

9. The method of claim 1, where a high-temperature treatment is executed to anneal a tunnel oxide and crystallize silicon layers of the multilayered stack of materials.

10. The method of claim 3, wherein the first doping type is p-type.

11. The method of claim 6, wherein the second doping type is n-type.
